(19) United States
(12) Patent Application Publication
(10) Pub. No.: US 2023/0275060 A1
(43) Pub. Date: Aug. 31, 2023

(54) LEADED SEMICONDUCTOR PACKAGE WITH LEAD MOLD FLASH REDUCTION

(71) Applicant: Texas Instruments Incorporated, Dallas, TX (US)

(72) Inventors: Xiaoling Kang, Chengdu City (CH); Xi Lin Li, Chengdu City (CH); Zi Qi Wang, Chengdu City (CH); Huo Yun Duan, Chengdu City (CH); Xiao Lin Kang, Chengdu City (CH)

(21) Appl. No.: 17/682,194

(22) Filed: Feb. 28, 2022

(51) Int. Cl. H01L 23/00

(52) U.S. Cl. CPC H01L 24/48; H01L 24/85; H01L 2224/48175; H01L 2224/48479; H01L 2224/48464; H01L 2224/85186; H01L 2224/85051; H01L 24/49; H01L 2224/49113; H01L 24/73; H01L 2224/73265; H01L 24/32; H01L 2224/32245; H01L 23/49555

(57) ABSTRACT

A semiconductor package includes a leadframe including a die pad and a plurality of leads including a first lead, wherein the first lead includes a first ball bond. A semiconductor die having a plurality of bond pads including a first bond pad is on the die pad including a second ball bond on the first bond pad and a stitch bond on the second ball bond. A first wirebond connection is between the first ball bond and the stitch bond.

### FIELD

This Disclosure relates to leaded semiconductor packages having a mold flash reduction technique for reducing the mold flash on the leads.

### BACKGROUND

Wirebonding is used in semiconductor device assembly to electrically connect contacts within a semiconductor package. A metal wire (e.g., gold, copper, etc.) has one end ball-bonded to a bond pad on semiconductor die, and another end stitch (or wedge) bonded to a lead of a leadframe. In order to form such connections, the metal wire is fed through a capillary associated with a moveable bond head. Some leads can have two bond wires, such as for high current connections for a power device. The respective wires in the case of a two-bond wire (double bond wire or double wire) connection can be separated from one another or in physical contact with one another.

For a ball bond, a ball is formed on the exposed end of the wire using an electronic flame off (EFO) mechanism. The ball is pulled against the end of the capillary and is then pressed into position on a pre-heated bond pad where a combination of heat, pressure, and ultrasonic vibration is used to cause the ball to adhere to the surface of the bond pad. With the ball end of the wire secured to the bond pad, the wire is payed out through the capillary as the bond head moves into position at the appropriate lead on the leadframe. A stitch bond is formed on the lead, and a tail of the wire is payed out through the capillary, clamped, and then cut. A new ball is then formed readying the wire end for the next ball bond, and the above-described cycle is repeated.

During the subsequent molding operation, some excess resin can end up coating part of the leads. This resin can affect the formation of the lead's solder profile and electrical conductivity when soldering to an application board. The excess resin is generally referred to as “resin-bleed”. The resin-bleed can appear clear and be called “clear-bleed” or more commonly can appear as a visible residue that is often referred to as “mold-flash”. Chemical deflashing and media deflashing methods are both commonly used in the industry to remove this excess resin on the leads.

### SUMMARY

This Summary is provided to introduce a brief selection of disclosed concepts in a simplified form that are further described below in the Detailed Description including the drawings provided. This Summary is not intended to limit the claimed subject matter's scope.

Disclosed aspects recognize strong conventional tail bond to lead adhesion can cause the lead to be pulled up during tail cutting of the bond wire by the wire bonding apparatus which is generally referred to herein as being a capillary tool. For a specific example, for a double bond wire connection having 2 mil diameter bond wires, because there are 2 bond wires attached to the single lead, the total upward tension during tail cutting can be greater than the maximum tension capacity of the connecting dam bar that connects between leads of adjacent leadframe units for a leadframe sheet. This situation can cause the lead to be raised up which has been recognized herein to cause mold flash on the lead.

Disclosed aspects include what is termed a reverse bond wire process because it applies tail cutting of the bond wire while the capillary tool is over the bond pad instead of conventional tail cutting while over the lead, which is applied to at least one lead of a leadframe having a die pad and a plurality of leads. Eliminating conventional tail cutting over the lead reduces mold flash on the leads for the leads that the disclosed process is applied to.

The reverse bond wire process comprises using a capillary tool utilizing a conductive wire forming a first ball bond on a bond pad of a semiconductor die that is on the die pad, then cutting off the wire, and then moving over the lead. Once the capillary tool is over the lead, a second ball bond is formed on the lead, and then there is paying out of the wire while moving towards the bond pad to form a loop, and then a stitch bond is formed on the first ball bond, followed by cutting the wire to provide a first wirebond connection. In contrast, a conventional wirebonding process starts by forming a ball bond on the bond pad of a semiconductor die that is on a die pad, forming a loop while moving to the lead, forming a stitch bond on the lead, and then finally cutting the tail while over the lead which as described above which can result in lifting up of the lead.

Disclosed aspects also include a semiconductor package that includes results from a reverse bond wire process used for generally only a portion of the leads, where the reverse bond wire process results in new loop shape for the bond wire(s). The semiconductor package includes a leadframe including a die pad and a plurality of leads including a first lead, wherein the first lead includes a first ball bond thereon. A semiconductor die having a plurality of bond pads including a first bond pad is on the die pad including a second ball bond on the first bond pad and a stitch bond is on the second ball bond. A first wirebond connection is between the first ball bond and the stitch bond. The first lead can include a double wirebond connection further comprising a second wirebond connection. The leads receiving the reverse bond wire process may be only the leads of the package that have the double wirebond connection.

### BRIEF DESCRIPTION OF THE DRAWINGS

Reference will now be made to the accompanying drawings, which are not necessarily drawn to scale, wherein:

FIG. 1A depicts a capillary tool having a bond wire therein conventionally positioned with a ball bond on a bond pad of a die that is on a die pad of a leadframe that is part of a leadframe sheet including a plurality of leadframe units, with the lead of one unit that includes the die pad, and a lead of another unit connected together to the lead by a dam bar which includes a half etch region. FIG. 1B depicts the results after the capillary tool was moved over a lead to form a loop, and then forming a stitch bond on the lead. FIG. 1C depicts the results after cutting a tale of the bond wire while over the lead.

FIGS. 2A-2E depict steps in an example wirebonding method, according to an example aspect. FIG. 2A depicts a capillary tool having a ball on its bottom end positioned over a bond pad of a semiconductor die after forming the ball which will be referred to in this example as being a first ball bond after contacting the first bond pad. FIG. 2B depicts results after cutting the tail of the bond wire and moving the capillary tool towards the lead.

FIG. 2C depicts the capillary tool positioned over the lead after forming a ball bond referred to herein as being a second ball bond on the lead. Once the second ball bond is formed on the lead, then the capillary tool will be moved up, where one can apply an ultrasonic generator (USG) current to help release the second ball bond from the capillary tool's hole during this upwards motion, so that the lift up force utilized can be minimized relative to conventional lift up forces. FIG. 2D shows results after paying out the wire while moving toward the bond pad. FIG. 2E depicts results after the moving reaches the bond pad to form a loop, and then stitch bonding to form a stitch bond on the first ball bond on the bond pad, and then cutting the tail of the wire to providing wirebond connection. The shape of the loop can be seen to point towards over the lead, whereas in a conventional bonding process shown in FIGS. 1B and 1C described above the loop instead points over the bond pad.

FIG. 3A is a top perspective view of a semiconductor package derived from a scanned scanning electron microscope (SEM) image after wirebond processing and before molding, having a conventional bonding arrangement comprising a ball bound on a die pad of the die, a second bond being a stitch bond to the leads, and a bond wire with a shape having a maximum height that is over the die clearly shown in FIG. 1C described above. Within the region shown enclosed by a dashed rectangle are six leads having double wire bond wire connections between those leads of the package and bond pads.

FIG. 3B is a top perspective view of a semiconductor package derived from a scanned SEM image after wirebond processing and before molding having a new loop shape resulting from a disclosed reverse bond wire process having a maximum height that is over the lead for the bond wires within the dashed box as shown in FIG. 2E. As with FIG. 3A, the region shown enclosed by a dashed rectangle are six leads having a disclosed double wire bond wire connections between those leads of the package and bond pads.

FIG. 4 is a cross-sectional depiction of a disclosed molded semiconductor package having at least one disclosed reverse wirebond shown as a loop. Leads are shown.

### DETAILED DESCRIPTION

Example aspects are described with reference to the drawings, wherein like reference numerals are used to designate similar or equivalent elements. Illustrated ordering of acts or events should not be considered as limiting, as some acts or events may occur in its different order and/or concurrently with other acts or events. Furthermore, some illustrated acts or events may not be required to implement a methodology in accordance with this Disclosure.

Also, the terms “connected to” or “connected with” (and the like) as used herein without further qualification are intended to describe either an indirect or direct electrical connection. Thus, if a first device “connects” to a second device, that connection can be through a direct electrical connection where there are only parasitics in the pathway, or through an indirect electrical connection via intervening items including other devices and connections. For indirect connecting, the intervening item generally does not modify the information of a signal but may adjust its current level, voltage level, and/or power level.

It has been found that lead mold flash can be caused by lead lifting due to the wire cutting operation during conventional wire bonding. Disclosed aspects include partial (meaning only some of the bond wires) reverse bond wire assembly to reduce lead deformation during wire cutting over the lead to reduce lead mold flash. A reverse wire bond refers to the wire bonder (capillary tool) instead of conventionally cutting the bond wire between the lead and the bond pad while over the lead (after a stitch bond), cutting the bond wire while over the bond pad of the semiconductor die. The first ball bond functions to protect the subsequent stitch bond formation process from damaging the bond pad. Disclosed reverse wire bonding also reduces the problem of nonstick on pad (NSOP) which is a defect in wire bonding that can affect front end assembly yields. In this condition, the imprint of the bond is left on the bond pad without the wire being attached. NSOP failures are generally costly because the entire device is rejected if there is one such failure on any of the bond pads.

The following terms now defined. A ball bond starts with the capillary tool first forming a free air ball generated by high current sparking on the wire which generally comprises copper or gold, where the free air ball shape looks like a ball. Then through the capillary a USG/force/scrub is used to flatten the ball and to bond the ball to a bond pad or a lead. A stitch bond is formed by the capillary tool paying out a wire loop, then the capillary tool applies USG/force/scrub to form the wire attached on the lead or a ball bonded previously, where the shape looks like a “fish tail”. The ball bonds can comprise flex bumps or ACCU bumps. Flex bump and ACCU bump are different bump types, and they utilize a different mode to cut off the wire after forming the first ball bond on the bond pad. Flex bumps have a folder on ball, which makes the ball size larger and can raise a bond pad opening concern, but it is good for bondability and to increase the wire to die clearance. An ACCU bump can provide a smaller ball size as compared to a flex bump due to not having a folder.

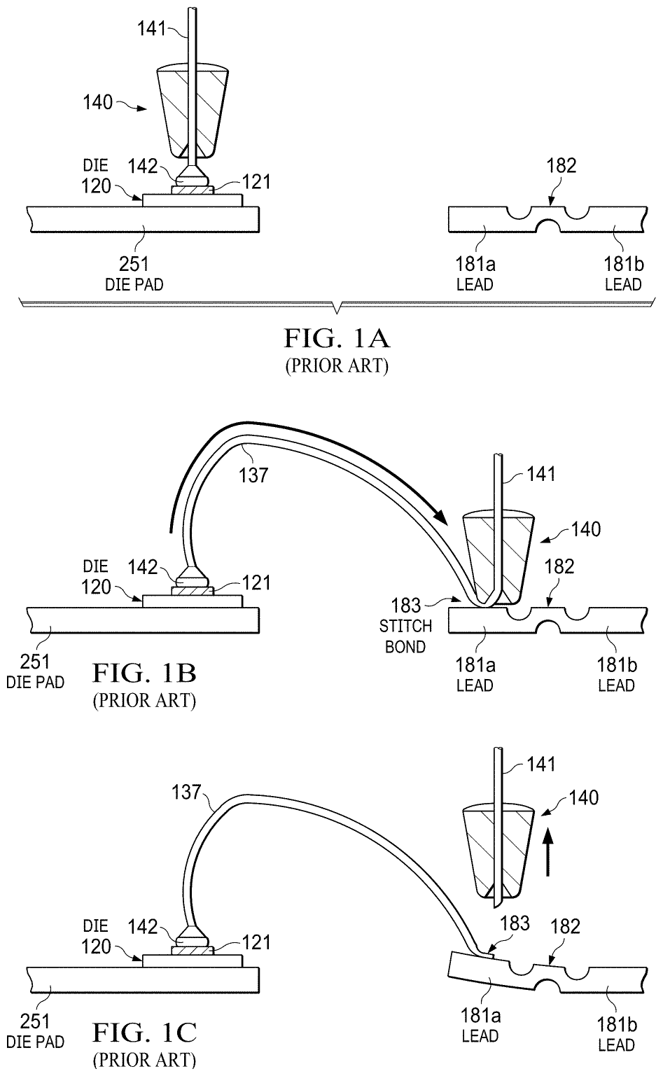

FIG. 1A depicts a capillary tool 140 shown having a wire 141 therein conventionally positioned with a ball bond 142 on a bond pad 121 of a die 120 that is on a die pad 251 of a leadframe that is part of a leadframe sheet including a plurality of leadframe units. Lead 181a of one unit includes the die pad 251, and a lead 181b of another unit connected together with lead 181a by a dam bar 182 is shown as a half etch region.

FIG. 1B depicts the results after the capillary tool 140 was moved over a lead 181a to form a loop 137, and then forming a stitch bond 183 on the lead 181a. FIG. 1C depicts the results after cutting a tale of the wire 141 over the lead 181a. The lead 181a can be seen to have been pulled up on its end as compared to the remainder of the lead due to strong lead adhesion between the stitch bond 183 on the lead 181a and the loop 137 on the lead end resulting in bending of the dam bar 182 and thus bending of the lead 181a, where the dam bar 182 physically connects leads of adjacent leadframe units of a leadframe sheet during the tail cutting process.

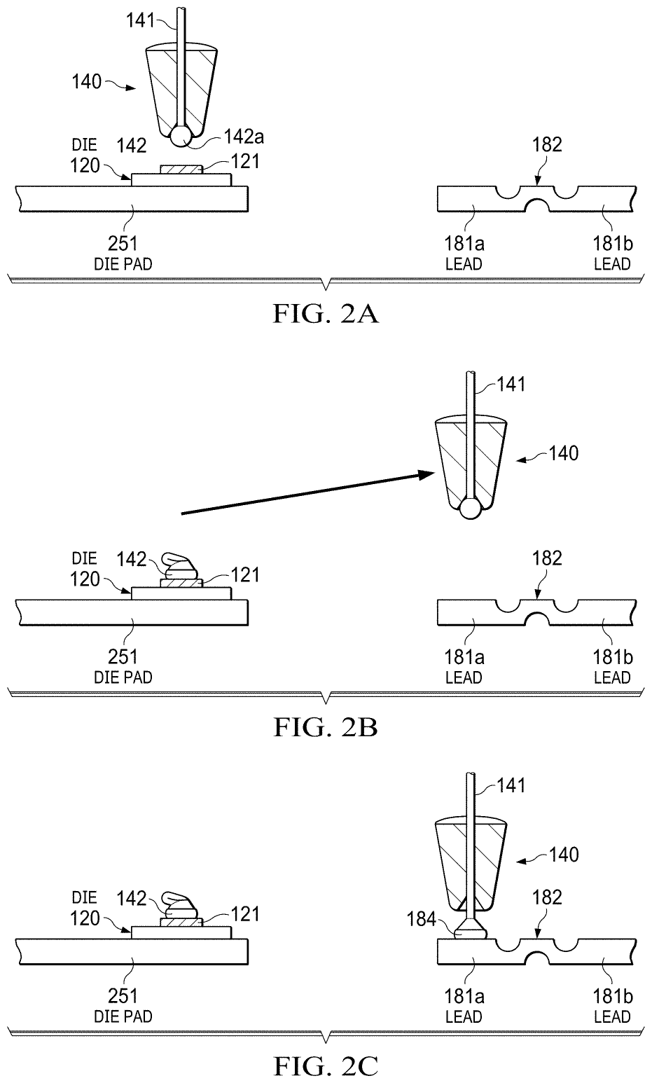

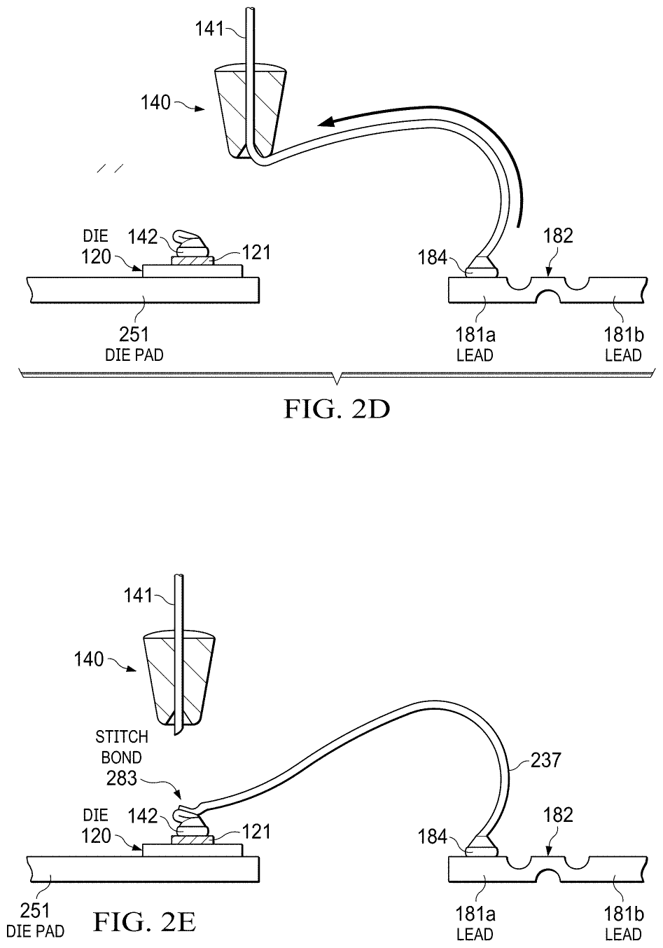

FIGS. 2A-2E depict steps in an example wirebonding method, according to an example aspect. To form double wires (a lead having a first wirebond connection and a second wirebond connection) this method described below is simply repeated. Also, in the case of double bond wires, as described above they can physically touch one another due to proximity on the same lead or be spaced apart from one another.

FIG. 2A depicts a capillary tool 140 having a ball 142a on its bottom end positioned over a first bond pad 121 of a semiconductor die 120 on a die pad 251 after forming the ball which will be referred to in this example when on the bond pad as being a first ball bond (which can also be called a bump) 142 (shown in FIG. 2B) after contacting the first bond pad 121 to distinguish it over the second ball bond 184 that is formed over the lead 181a as described below. FIG. 2B depicts results after cutting the tail of the wire 141 to provide the first ball bond 142, and then moving the capillary tool 140 towards the lead 181a.

FIG. 2C depicts the capillary tool 140 positioned over the lead 181a after forming a ball bond referred to herein as being a second ball bond 184 on the lead. Once the second ball bond 184 is formed on the lead 181a, then the capillary tool 140 will be moved up, where one can apply a USG current of at least 120 mA to about 150 mA to help release the second ball bond 184 from the capillary tool's hole during this upwards motion. This enables the lift up force utilized by the capillary tool 140 to be minimized relative to conventional lift up forces. The lower lift up force utilized will not pull up the lead, consequently there will generally be no lead deformation after forming the second ball bond 184 on the lead 181a is completed, and there is also no need to conventionally cut off the tail of the wire 141 while over the lead.

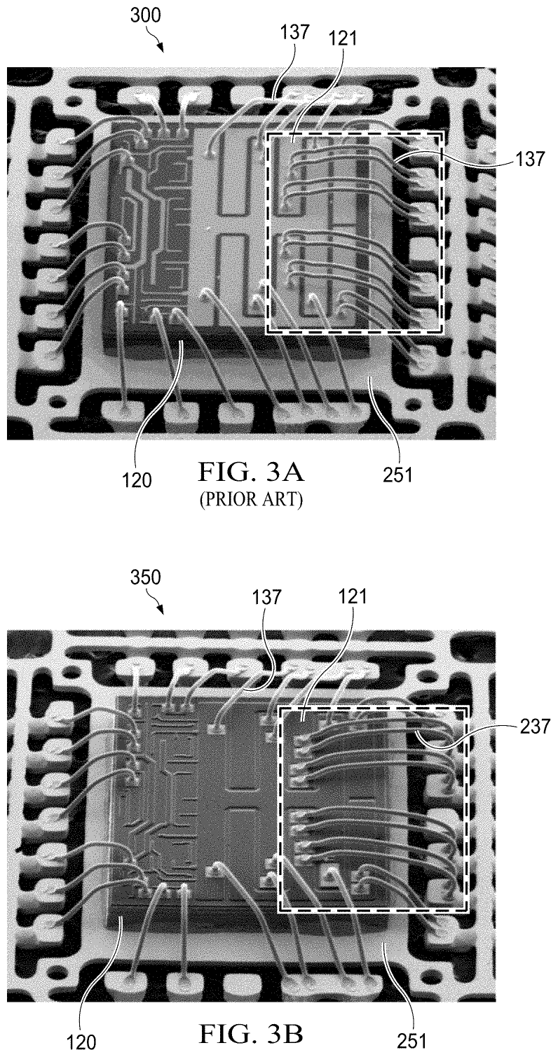

FIG. 2D shows results after paying out the wire 141 while moving the capillary tool 140 toward the bond pad 121. FIG. 2E depicts results after the moving reaches the bond pad 121 to form a loop 237, and stitch bonding to form a stitch bond 283 on the first ball bond 142 on the bond pad 121, and then cutting the tail of the wire 141 to provide a wirebond connection. This cutting step is the last step of the reverse bond wire process, and the tail strength of the wire 141 will generally not be sufficient to lift up the bond pad 121 on die 120 which is attached securely to die pad 251 is generally held strongly by the first ball bond 142. The shape of the loop 237 can be seen to point towards over the lead 181a, whereas in a conventional wire bonding process shown in FIG. 3A described below the loop 137 instead points over the bond pad 121.

FIG. 3A is a top perspective view of a semiconductor package 300 derived from a scanned SEM image after wirebond processing and before molding, having a conventional bonding arrangement. The conventional bonding arrangement comprises a ball bound on bond pads of the semiconductor die on a die pad 251 including bond pad 121 having double bond wires, a second bond being a stitch bond to the leads, and bond wires throughout shaped as a loop 137 having a conventional shape with a maximum height that is over the die 120 clearly shown in FIG. 1C described above. Within the region shown enclosed by a dashed rectangle are six leads having double bond wire connections (first and second wirebond connections) with each wire formed as a conventional loop 137 between those leads of the package 300 and the bond pads including bond pad 121. The other bond wires of the package 300 are also formed as a loop 137.

FIG. 3B is a top perspective view of a semiconductor package 350 derived from a scanned SEM image after wirebond processing and before molding having bond wires with a new loop shape resulting from a disclosed reverse bond wire process. As with package 300, within the region shown enclosed by a dashed rectangle are six leads having double bond wire connections with each wire formed as a loop 237 between those leads of the package 350 and the bond pads including bond pad 121 of the die 120 on the die pad 251. Loop 237 can be seen to have a maximum height over the lead which is also shown in FIG. 2E. The other leads of the package 350 are single wire connections for the other leads with the bond wires formed as loop 137. The double wirebond connections are shown with the respective wires on the lead being spaced apart.

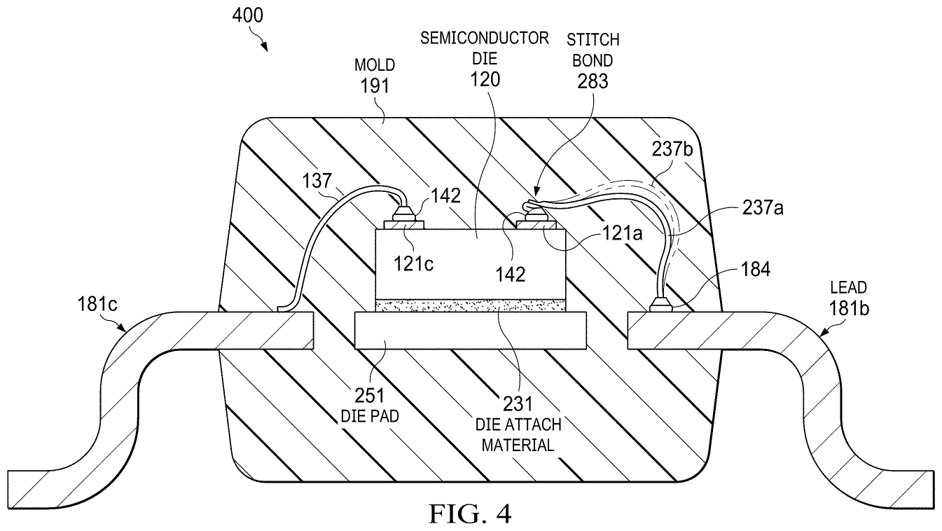

FIG. 4 shows a cross-sectional view of a wirebonded semiconductor package 400 having a semiconductor die 120 including a top surface including bond pads 121a and 121b, and leads 181b, 181c, with bond wires in between. The wirebonded semiconductor package 400 includes a die pad 251 provided by the leadframe, where a bottom side of the semiconductor die 120 is attached to the die pad 251 by a die attach material 231. The mold material is shown as 191. The bond wires include disclosed double bond wire connections including a first wirebond connection shown as a loop 237a and a second wirebond connection shown as a loop (shown in phantom) 237b with the same shape as loop 237a that are spaced apart from one another, both shown between a stitch bond 283 that is on a ball bond 142 on the bond pad 121a, and a ball bond 184 on the lead 181b. The other lead 181c shown is connected by a conventional bond wire shown as loop 137 from the lead 181c to a ball bond 142 on the bond pad 121c.

An experiment was performed to compare the yield results after molding from conventional wire bonding used for the conventional semiconductor package 300 shown in FIG. 3A as compared to disclosed reverse bond wires on a disclosed semiconductor package 350 shown in FIG. 3B. This experiment confirmed that disclosed reverse bond wires can almost completely eliminate the lead mold flash problem. The conventional bonding used for the conventional semiconductor package 300 for all leads had a yield loss due to mold flash without deflash processing of 50% to 100%, and after deflash processing the yield loss was only slightly reduced to 40% to 95%. For the disclosed reverse bond wires used for the double bond wires on semiconductor package 350 the yield loss due to lead mold flash without mold flash removal processing was 0.9%, confirming disclosed reverse bond wires can almost completely eliminate the lead mold flash problem. This enables deflash processing to be omitted.

Disclosed aspects can be integrated into a variety of assembly flows to form a variety of different semiconductor packages and related products. The semiconductor package can comprise single IC die or multiple IC die, such as configurations comprising a plurality of stacked IC die, or laterally positioned IC die. A variety of package substrates may be used. The IC die may include various elements therein and/or layers thereon, including barrier layers, dielectric layers, device structures, active elements and passive elements including source regions, drain regions, bit lines, bases, emitters, collectors, conductive lines, conductive vias, etc. Moreover, the IC die can be formed from a variety of processes including bipolar, insulated-gate bipolar transistor (IGBT), CMOS, BiCMOS and MEMS.

Those skilled in the art to which this Disclosure relates will appreciate that many variations of disclosed aspects are possible within the scope of the claimed invention, and further additions, deletions, substitutions and modifications may be made to the above-described aspects without departing from the scope of this Disclosure.

1. A semiconductor package, comprising:
a leadframe including a die pad and a plurality of leads including a first lead, wherein the first lead includes a first ball bond;
a semiconductor die attached to the die pad, the semiconductor die having a plurality of bond pads including a first bond pad including a second ball bond on the first bond pad and a stitch bond on the second ball bond, and
a first wirebond connection between the first ball bond and the stitch bond.

2. The semiconductor package of claim 1, wherein the plurality of leads include a first plurality of leads having a second wirebond connection between the first ball bond and the stitch bond.

3. The semiconductor package of claim 2, further including a second plurality of leads connected to a single wire bond, wherein a number of the second plurality of leads is greater than a number of the first plurality of leads.

4. The semiconductor package of claim 1, wherein the semiconductor die comprises a power device.

5. The semiconductor package of claim 1, wherein a loop of the wirebond connection has a shape having a maximum height that is over the first lead.

6. The semiconductor package of claim 1, further comprising molding that encapsulates the semiconductor die.

7. The semiconductor package of claim 1, wherein the first wirebond connection and the second wirebond connection are spaced apart from one another.

8. The semiconductor package of claim 2, wherein a loop of the wirebond connection points toward the first lead.

9. The semiconductor package of claim 1, wherein the leadframe is a leaded leadframe.

10. A wirebonding method, comprising:
forming at a first end of a conductive wire inserted within a capillary tool a first ball bond on a bond pad of a semiconductor die that is on a die pad of a first leadframe that includes a plurality of leads including a first lead;
a first cutting of a tail of the conductive wire;
moving the capillary tool to over the first lead;
forming a second ball bond on the first lead;
after forming the second ball bond, without cutting the conductive wire, releasing the second ball bond from a hole of the capillary tool, then moving the capillary tool to over the first ball bond to form a loop, and
forming a stitch bond on the first ball bond then a second cutting of a tail of the conductive wire to provide a first wirebond connection.

11. The method of claim 10, wherein the method is repeated so that the conductive wire comprises a double wire further including a second wirebond connection.

12. The method of claim 10, wherein the first leadframe is part of a leadframe sheet including a plurality of other leadframes including a second leadframe having a second lead physically connected to the first lead by a dam bar that includes a half etch thickness.

13. The method of claim 10, wherein the releasing of the second ball bond comprises the capillary tool applying ultrasonic energy using an ultrasonic generator (USG) current of at least 120 mA.

14. The method of claim 13, wherein the USG current is at least 150 mA.

15. The method of claim 10, wherein the loop has a shape having a maximum height over the first lead.

16. The method of claim 10, wherein the semiconductor die comprises a power device.

17. The method of claim 10, wherein the method is exclusive of a deflashing step.

18. The method of claim 10, further comprising forming a mold compound that encapsulates the semiconductor die.

19. The method of claim 11, wherein the first wirebond connection and the second wirebond connection are spaced apart from one another.

20. The method of claim 10, wherein the loop points toward the first lead.
